(19) United States
(12) Patent Application Publication
(10) Pub. No.: US 2025/0296876 A1
(43) Pub. Date: Sep. 25, 2025

(54) SOLID PRODUCT, OPTICAL MEMBER, METHOD FOR MANUFACTURING SOLID PRODUCT, SURFACE FORMATION METHOD, SPECTACLES, TOUCH PANEL, SMARTPHONE, AND TABLET TERMINAL

(71) Applicant: CANON OPTRON, INC., Ibaraki (JP)

(72) Inventors: Manabu KONAGAI, Ibaraki (JP); Moritada TOMATSU, Ibaraki (JP)

(21) Appl. No.: 19/230,565

(22) Filed: Jun. 6, 2025

Related U.S. Application Data
(63) Continuation of application No. PCT/JP2023/046812, filed on Dec. 26, 2023.

(30) Foreign Application Priority Data
Jan. 16, 2023 (JP) 2023-004634

(51) Int. Cl. C03C 17/30

(52) U.S. Cl. CPC C03C 17/30; C03C 2217/76; C03C 2217/78; C03C 2218/151

(57) ABSTRACT

This solid product has a silicon-oxide-containing layer and a polymer brush on the silicon-oxide-containing layer, the solid product being characterized in that the polymer brush has a moiety having a C14-65 alkyl group, and the moiety having an alkyl group is bonded to the silicon oxide via the oxygen atom.

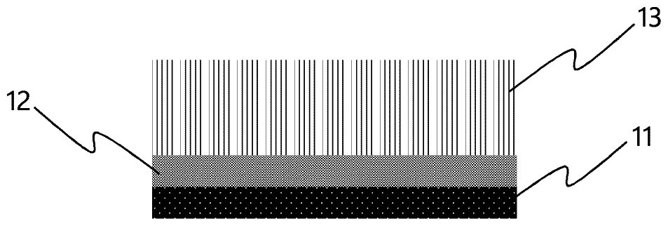

### CROSS-REFERENCE TO RELATED APPLICATION

This is a continuation of International Application No. PCT/JP2023/046812, filed on Dec. 26, 2023, and designated the U.S., and claims priority from Japanese Patent Application No. 2023-004634 filed on Jan. 16, 2023, the entire contents of which are incorporated herein by reference.

### BACKGROUND OF THE INVENTION

### Field of the Invention

The present disclosure relates to a solid product having excellent scratch resistance and an excellent long-term antifouling property, a method for manufacturing the solid product, an optical member including the solid product, and spectacles, a touch panel, a smartphone, and a tablet terminal that include the optical member.

The present disclosure relates to a laminated body having excellent scratch resistance and an excellent long-term antifouling property, a method for manufacturing the laminated body, an optical member including the laminated body, and spectacles, a touch panel, a smartphone, and a tablet terminal that include the optical member.

Further, the present disclosure relates to a surface formation material and a surface formation method that form a surface having excellent scratch resistance and an excellent long-term antifouling property.

### Description of the Related Art

An optical member such as an optical filter and a spectacle lens, and an article such as a touch panel and a smartphone include an outermost layer on which an antifouling film is formed in order to prevent adhesion of dirt such as a fingerprint, sebum, sweat, and cosmetics, and facilitate removal of the dirt. The antifouling film is required to have an excellent antifouling property (water repellency and oil repellency) and excellent scratch resistance, and an organic fluorine compound (PFAS) typified by perfluorooctanoic acid (PFOA) and perfluorosulfonic acid (PFOS) is often used. However, regulation of the PFAS as a material with a concern about a possibility of affecting an environment and an ecosystem is being discussed in various countries, and the antifouling film may be unusable in the future, and thus the antifouling film not including the PFAS is desired.

As the antifouling film not including the PFAS, an antifouling coating agent containing a quaternary ammonium chloride of an amino-modified silicone compound, and an aliphatic amine alkylene oxide adduct is disclosed in Japanese Patent Application Publication No. 2012-241187. Japanese Patent Application Publication No. 2012-241187 discloses that a hard surface acquired by using the antifouling coating agent has an excellent characteristic in terms of an antifouling property.

On the other hand, it is generally known that a surface having excellent durability is acquired from a molecular organization (polymer brush) having a structure like a toothbrush in which string-shaped high molecules are grown on a material surface. The polymer brush can be formed on a foundation layer by forming the foundation layer having a function of a polymerization initiator on a material surface by coating, and by causing a polymerization reaction.

WO2019/131872A1 discloses a polymer brush formation substrate including a polymerization initiation layer, and a precursor liquid for manufacturing the polymer brush formation substrate.

### SUMMARY OF THE INVENTION

As a result of discussion by the present inventors, a silicone-based antifouling film disclosed in Japanese Patent Application Publication No. 2012-241187 has an excellent characteristic in terms of an antifouling property. However, there are problems that scratch resistance is low, scratches are made by repeatedly wiping off dirt, and an antifouling property decreases in use over a long period of time.

Further, WO2019/131872A1 discloses the polymer brush formation substrate including the polymerization initiation layer, and the precursor liquid for manufacturing the polymer brush formation substrate. However, since a polymerization reaction is used in WO2019/131872A1, control of a molecular weight of a polymer brush to be formed and the like are difficult, and thus the present inventors have considered a problem of difficulty in controlling a structure of the polymer brush. In addition, WO2019/131872A1 does not mention scratch resistance and a long-term antifouling property of a formed polymer brush.

The solution means described in Japanese Patent Application Publication No. 2012-241187 and WO2019/131872A1 are not sufficient in terms of compatibility between scratch resistance and a long-term antifouling property in an antifouling film, and a surface having both of excellent scratch resistance and an excellent long-term antifouling property is desired.

The present disclosure provides a solid product having both excellent scratch resistance and an excellent long-term antifouling property, a method for manufacturing the solid product, an optical member, spectacles, a touch panel, a smartphone, and a tablet terminal.

The present disclosure provides a laminated body having both of excellent scratch resistance and an excellent long-term antifouling property, a method for manufacturing the laminated body, an optical member, spectacles, a touch panel, a smartphone, and a tablet terminal.

Further, the present disclosure provides a surface formation material and a surface formation method that form a surface having excellent scratch resistance and an excellent long-term antifouling property.

A solid product according to the present disclosure is a solid product including:
a layer containing silicon oxide; and
a polymer brush on the layer containing the silicon oxide, wherein
the polymer brush constitutes a surface of the solid product,
the polymer brush includes a site having an alkyl group having a carbon number of 14 or more and 65 or less, and
the site having the alkyl group is bonded to the silicon oxide via an oxygen atom.

Further, an optical member according to the present disclosure is an optical member including the solid product described above.

Furthermore, a spectacle according to the present disclosure is a spectacle including the optical member described above.

In addition, a touch panel according to the present disclosure is a touch panel including the optical member described above.

Moreover, a smartphone according to the present disclosure is a smartphone including the optical member described above.

Further, a tablet terminal according to the present disclosure is a tablet terminal including the optical member described above.

Further, a method for manufacturing the solid product according to the present disclosure is a method for manufacturing a solid product including: in this order, a first vapor deposition step of vacuum-depositing a first vapor deposition material including silicon oxide, and forming a layer containing the silicon oxide; and a second vapor deposition step of vacuum-depositing a second vapor deposition material including a first compound that includes a site having an alkyl group having a carbon number of 14 or more and 65 or less and has a hydroxyl group, and forming the polymer brush.

A laminated body according to the present disclosure is a laminated body including:
a first layer; and
a polymer brush layer on the first layer, wherein
the first layer contains silicon oxide,
the polymer brush layer constitutes a surface of the laminated body,
a polymer brush included in the polymer brush layer includes a site having an alkyl group having a carbon number of 14 or more and 65 or less, and
the site having the alkyl group is bonded to the silicon oxide via an oxygen atom.

Further, an optical member according to the present disclosure is an optical member including the laminated body described above.

Furthermore, a spectacle according to the present disclosure is a spectacle including the optical member described above.

In addition, a touch panel according to the present disclosure is a touch panel including the optical member described above.

Moreover, a smartphone according to the present disclosure is a smartphone including the optical member described above.

Further, a tablet terminal according to the present disclosure is a tablet terminal including the optical member described above.

Further, a method for manufacturing the laminated body according to the present disclosure is a method for manufacturing a laminated body including: in this order, a first vapor deposition step of vacuum-depositing a first vapor deposition material including silicon oxide, and forming the first layer; and a second vapor deposition step of vacuum-depositing a second vapor deposition material including a first compound that includes a site having an alkyl group having a carbon number of 14 or more and 65 or less and has a hydroxyl group, and forming the polymer brush layer.

Furthermore, a surface formation material according to the present disclosure is a surface formation material including a first compound that includes a site having an alkyl group having a carbon number of 14 or more and 65 or less and has a hydroxyl group.

In addition, a surface formation method according to the present disclosure is a surface formation method using a vacuum deposition method, and includes:
in this order,
a first vapor deposition step of vacuum-depositing a first vapor deposition material including silicon oxide, and forming a layer containing the silicon oxide; and
a second vapor deposition step of vacuum-depositing a second vapor deposition material including a first compound that includes a site having an alkyl group having a carbon number of 14 or more and 65 or less and has a hydroxyl group.

According to the present disclosure, it is possible to provide a solid product including a surface having both of excellent scratch resistance and an excellent long-term antifouling property, a method for manufacturing the solid product, a laminated body, a method for manufacturing the laminated body, an optical member, spectacles, a touch panel, a smartphone, and a tablet terminal. Further, the present disclosure can provide a surface formation material and a surface formation method that form a surface having both of excellent scratch resistance and an excellent long-term antifouling property.

Further features of the present invention will become apparent from the following description of exemplary embodiments with reference to the attached drawings.

### BRIEF DESCRIPTION OF THE DRAWINGS

The FIGURE is a schematic diagram illustrating a configuration of a solid product or a laminated body according to the present disclosure.

### DESCRIPTION OF THE EMBODIMENTS

Hereinafter, while suitable embodiments are presented, embodiments of a solid product, a method for manufacturing the solid product, a laminated body, a method for manufacturing the laminated body, an optical member, spectacles, a smartphone, a tablet terminal, a surface formation material, and a surface formation method according to the present disclosure will be described. The present disclosure is not limited to the embodiments below.

In the present disclosure, description of “XX or more and YY or less” and “XX to YY” representing a numerical range means a numerical range including a lower limit and an upper limit that are endpoints unless otherwise specified. Furthermore, when numerical ranges are described in stages, an upper limit and a lower limit of each of the numerical ranges can be freely combined.

In the present disclosure, a polymer brush refers to a structure in which string-shaped high molecules are immobilized on a base material surface, and refers to, for example, a molecular organization of a structure in which string-shaped high molecules are disposed like a brush on a base material surface. In the present disclosure, a site having an alkyl group and a site having a dimethyl silicone chain correspond to a string-shaped high molecule.

In the method for manufacturing a polymer brush formation substrate described in WO2019/131872A1, a polymer brush is formed by applying monomers to a substrate or immersing a substrate in monomers, and causing a polymerization reaction. When the polymer brush is formed by such a polymerization reaction, control of a molecular weight of the polymer brush and the like is difficult, and thus control of a structure of the polymer brush is conceivably difficult. Thus, it is conjectured that scratch resistance and a long-term antifouling property of the antifouling film described in WO2019/131872A1 are not necessarily sufficient.

According to the present disclosure, the polymer brush includes a site having an alkyl group having a specific carbon number, and thus it is conceivable that a high-density and uniform brush-shaped molecular organization is formed, and a solid product including a surface having excellent scratch resistance and an excellent long-term antifouling property is acquired.

Further, according to the manufacturing method in the present disclosure, by forming the polymer brush by vacuum-depositing a vapor deposition material including a first compound that includes a site having an alkyl group having a specific carbon number and has a hydroxyl group, it is conceivable that molecular length control of the polymer brush is facilitated, a high-density and uniform brush-shaped molecular organization is more likely to be formed, and a solid product including a surface having excellent scratch resistance and an excellent long-term antifouling property can be manufactured.

According to the present disclosure, the polymer brush included in a polymer brush layer includes a site having an alkyl group having a specific carbon number, and thus it is conceivable that a high-density and uniform brush-shaped molecular organization is formed, and a laminated body having excellent scratch resistance and an excellent long-term antifouling property is acquired.

Further, according to the manufacturing method in the present disclosure, by forming the polymer brush layer by vacuum-depositing a vapor deposition material including a first compound that includes a site having an alkyl group having a specific carbon number and has a hydroxyl group, and thus it is conceivable that molecular length control of the polymer brush is facilitated, a high-density and uniform brush-shaped molecular organization is more likely to be formed, and a laminated body having excellent scratch resistance and an excellent long-term antifouling property can be manufactured.

### <Solid Product>

The solid product including a surface according to the present disclosure will be described.

The solid product includes a layer containing silicon oxide and a polymer brush on the layer containing the silicon oxide. Further, the polymer brush constitutes a surface of the solid product. Furthermore, the polymer brush includes a site having an alkyl group having a carbon number of 14 or more and 65 or less. Moreover, the site having the alkyl group having the carbon number of 14 or more and 65 or less is bonded to the silicon oxide via an oxygen atom.

The polymer brush includes the site having the alkyl group having the carbon number of 14 or more and 65 or less. Further, the carbon number of the alkyl group is preferably 16 or more and 60 or less, more preferably 18 or more and 60 or less, and further preferably 18 or more and 40 or less. Further, the alkyl group may be a straight chain or may have a branch, and is preferably a straight-chain alkyl group. Furthermore, the site having the alkyl group is preferably a straight-chain aliphatic structure, and is more preferably a straight-chain alkyl group. With such a structure, a high-density and uniform brush-shaped molecular organization is formed, and a solid product including a surface having excellent scratch resistance and an excellent long-term antifouling property is acquired.

The site having the alkyl group is a site having a structure indicated by a general formula: [CₙH₂ₙ₊₁]—. n in the formula indicates a carbon number of the alkyl group, a preferable range of n is 14 or more and 65 or less, a more preferable range is 16 or more and 60 or less, a further preferable range is 18 or more and 60 or less, and a specifically preferable range is 18 or more and 40 or less.

With a carbon number of the alkyl group in the range described above, a high-density and uniform brush-shaped molecular organization is formed, and a solid product including a surface having excellent scratch resistance and an excellent long-term antifouling property is acquired. When a carbon number is less than 14, a high-density and uniform brush-shaped molecular organization is less likely to be formed, and thus scratch resistance and an antifouling property decrease. Further, when a carbon number exceeds 65, a high-density and uniform brush-shaped molecular organization is less likely to be formed, and thus scratch resistance and an antifouling property decrease.

A carbon number of the alkyl group can be adjusted by changing a kind of the first compound that includes the site having the alkyl group and has the hydroxyl group.

The site having the alkyl group may further have an oxyalkylene group such as oxyethylene group-(CH₂)₂—O— and oxypropylene group-(CH(CH₃)CH₂)—O—, and preferably has an oxyethylene group.

The site having the alkyl group and the oxyethylene group is a site having a structure indicated by a general formula: [C_{n′}H_{2n′+1}]—O—[(CH₂)₂O]ₘ—. n′ in the formula indicates a carbon number in the alkyl group, and m in the formula indicates a degree of polymerization of the oxyethylene group. A preferable range of n′+2m indicating a total of a carbon number of the alkyl group and a carbon number of the oxyethylene group in the site having the alkyl group and the oxyethylene group is 14 or more and 65 or less, a more preferable range is 16 or more and 60 or less, a further preferable range is 18 or more and 60 or less, and a specifically preferable range is 18 or more and 40 or less. Further, the alkyl group may be a straight chain or may have a branch, and is preferably a straight-chain alkyl group. Furthermore, the site having the alkyl group and the oxyethylene group is preferably a straight-chain alkyl group having the oxyethylene group.

With a total of a carbon number of the alkyl group and a carbon number of the oxyethylene group in the range described above, a high-density and uniform brush-shaped molecular organization is more likely to be formed, and a solid product including a surface having excellent scratch resistance and an excellent long-term antifouling property is more likely to be acquired. When a carbon number is less than 14, a high-density and uniform brush-shaped molecular organization is less likely to be formed, and scratch resistance and an antifouling property are more likely to decrease. Further, when a carbon number exceeds 65, a high-density and uniform brush-shaped molecular organization is less likely to be formed, and thus scratch resistance and an antifouling property are more likely to decrease.

A degree of polymerization of the oxyethylene group is not particularly limited, and may be 1 to 20, may be 1 to 15, and may be 1 to 10.

A total of a carbon number of the alkyl group and a carbon number of the oxyalkylene group, and a degree of polymerization of the oxyalkylene group can be adjusted by changing a kind of the first compound that includes the site having the alkyl group and the oxyalkylene group and has the hydroxyl group.

In the layer containing the silicon oxide, the silicon oxide indicates a compound represented by SiOx (x is 1 to 2, for example), SiO₂ in a composite inorganic oxide such as SiO₂—Al₂O₃, and the like. Herein, the layer containing the silicon oxide is bonded to the site forming the polymer brush and having the alkyl group via the oxygen atom. In other words, the site having the alkyl group is bonded to the silicon oxide via the oxygen atom. In this way, durability of the polymer brush can be improved, and scratch resistance of the solid product can be improved. Herein, an aspect of the bond is a covalent bond. Further, an aspect of bonding via the oxygen atom may be an aspect in which the site forming the polymer brush and having the alkyl group and the layer containing the silicon oxide are directly bonded, or may be an aspect in which the site and the layer are indirectly bonded via another coupling group.

With the layer containing the silicon oxide, an active point can be formed in the silicon oxide included in the layer. As a result, the site having the alkyl group in the polymer brush is more likely to be bonded to the silicon oxide via the oxygen atom. In other words, the polymer brush is more likely to be formed on the surface of the solid product. Examples of a method for forming such an active point include a method for forming a layer containing silicon oxide by a first vapor deposition step described below, and a method for reforming a surface by irradiating a base material with ultraviolet rays, plasma, and an ion beam.

Examples of a compound that may be included in the layer containing the silicon oxide include silicon dioxide (SiO₂), alumina added-silicon dioxide (Al₂O₃added-SiO₂), and the like. However, the compound containing the silicon oxide is not limited to these. Further, the layer containing the silicon oxide may include an inorganic oxide such as indium tin oxide (ITO) and titanium dioxide (TiO₂). The inorganic oxide may be a composite oxide.

### <Laminated Body>

The laminated body according to the present disclosure will be described.

The laminated body includes a first layer, and a polymer brush layer on the first layer. Further, the first layer contains silicon oxide. Furthermore, the polymer brush layer constitutes a surface of the laminated body. In addition, the polymer brush included in the polymer brush layer includes a site having an alkyl group having a carbon number of 14 or more and 65 or less. Moreover, the site having the alkyl group having the carbon number of 14 or more and 65 or less is bonded to the silicon oxide via an oxygen atom.

The polymer brush included in the polymer brush layer includes the site having the alkyl group having the carbon number of 14 or more and 65 or less. Further, the carbon number of the alkyl group is preferably 16 or more and 60 or less, more preferably 18 or more and 60 or less, and further preferably 18 or more and 40 or less. Further, the alkyl group may be a straight chain or may have a branch, and is preferably a straight-chain alkyl group. Furthermore, the site having the alkyl group is preferably a straight-chain aliphatic structure, and is more preferably a straight-chain alkyl group. With such a structure, a high-density and uniform brush-shaped molecular organization is formed, and a laminated body having excellent scratch resistance and an excellent long-term antifouling property is acquired.

The site having the alkyl group is a site having a structure indicated by a general formula: [CₙH₂ₙ₊₁]—. n in the formula indicates a carbon number of the alkyl group, a preferable range of n is 14 or more and 65 or less, a more preferable range is 16 or more and 60 or less, a further preferable range is 18 or more and 60 or less, and a specifically preferable range is 18 or more and 40 or less.

With a carbon number of the alkyl group in the range described above, a high-density and uniform brush-shaped molecular organization is formed, and a laminated body having excellent scratch resistance and an excellent long-term antifouling property is acquired. When a carbon number is less than 14, a high-density and uniform brush-shaped molecular organization is less likely to be formed, and thus scratch resistance and an antifouling property decrease. Thus, scratch resistance and an antifouling property decrease. Further, when a carbon number exceeds 65, a high-density and uniform brush-shaped molecular organization is less likely to be formed, and thus scratch resistance and an antifouling property decrease.

A carbon number of the alkyl group can be adjusted by changing a kind of the first compound that includes the site having the alkyl group and has the hydroxyl group.

The site having the alkyl group may further have an oxyalkylene group such as oxyethylene group-(CH₂)₂—O— and oxypropylene group-(CH(CH₃)CH₂)—O—, and preferably has an oxyethylene group.

The site having the alkyl group and the oxyethylene group is a site having a structure indicated by a general formula: [C_{n′}H_{2n′+1}]—O—[(CH₂)₂O]ₘ—. n′ in the formula indicates a carbon number in the alkyl group, and m in the formula indicates a degree of polymerization of the oxyethylene group. A preferable range of n′+2m indicating a total of a carbon number of the alkyl group and a carbon number of the oxyethylene group in the site having the alkyl group and the oxyethylene group is 14 or more and 65 or less, a more preferable range is 16 or more and 60 or less, a further preferable range is 18 or more and 60 or less, and a specifically preferable range is 18 or more and 40 or less. Further, the alkyl group may be a straight chain or may have a branch, and is preferably a straight-chain alkyl group. Furthermore, the site having the alkyl group and the oxyethylene group is preferably a straight-chain alkyl group having the oxyethylene group.

With a total of a carbon number of the alkyl group and a carbon number of the oxyethylene group in the range described above, a high-density and uniform brush-shaped molecular organization is formed, and a laminated body having excellent scratch resistance and an excellent long-term antifouling property is acquired. When a carbon number is less than 14, a high-density and uniform brush-shaped molecular organization is less likely to be formed, and scratch resistance and an antifouling property decrease. Further, when a carbon number exceeds 65, a high-density and uniform brush-shaped molecular organization is less likely to be formed, and thus scratch resistance and an antifouling property decrease.

A degree of polymerization of the oxyethylene group is not particularly limited, and may be 1 to 20, may be 1 to 15, and may be 1 to 10.

A total of a carbon number of the alkyl group and a carbon number of the oxyalkylene group, and a degree of polymerization of the oxyalkylene group can be adjusted by changing a kind of the first compound that includes the site having the alkyl group and the oxyalkylene group and has the hydroxyl group.

The first layer contains the silicon oxide. The silicon oxide indicates a compound represented by SiOx (x is 1 to 2, for example), SiO₂ in a composite inorganic oxide such as SiO₂—Al₂O₃, and the like. Herein, the first layer is a layer that contains silicon oxide and is bonded to the site forming the polymer brush and having the alkyl group via the oxygen atom. In other words, the site having the alkyl group is bonded to the silicon oxide via the oxygen atom. In this way, durability of the polymer brush can be improved, and scratch resistance of the laminated body can be improved. Herein, an aspect of the bond is a covalent bond. Further, an aspect of bonding via the oxygen atom may be an aspect in which the site forming the polymer brush and having the alkyl group and the layer containing the silicon oxide are directly bonded, or may be an aspect in which the site and the layer are indirectly bonded via another coupling group.

With the layer containing the silicon oxide, an active point can be formed in the silicon oxide included in the layer. As a result, the site having the alkyl group in the polymer brush is more likely to be bonded to the silicon oxide via the oxygen atom. In other words, the polymer brush is more likely to be formed on the surface of the solid product. Examples of a method for forming such an active point include a method for forming a layer containing silicon oxide by a first vapor deposition step described below, and a method for reforming a surface by irradiating a base material with ultraviolet rays, plasma, and an ion beam.

Examples of a compound that may be included in the first layer include silicon dioxide (SiO₂), alumina (Al₂O₃), alumina added-silicon dioxide (Al₂O₃added-SiO₂), and the like. However, the compound containing the silicon oxide is not limited to these. Further, the first layer may include an inorganic oxide such as indium tin oxide (ITO) and titanium dioxide (TiO₂). The inorganic oxide may be a composite oxide.

In the solid product and the laminated body according to the present disclosure, the polymer brush preferably further includes a site having a dimethyl silicone chain having a silicon number of 3 or more and 110 or less. With the site having the dimethyl silicone chain, water repellency and oil repellency (antifouling property) can be further enhanced.

The site having the dimethyl silicone chain is a site having a structure indicated by a general formula: —[Si(CH₃)₂O]ᵢ—. i in the formula indicates a degree of polymerization of the dimethyl silicone chain, i.e., a silicon number in the dimethyl silicone chain. A preferable range of i is 3 or more and 110 or less, a more preferable range is 3 or more and 100 or less, and a further preferable range is 3 or more and 50 or less.

The site having the dimethyl silicone chain may further have an alkylene group such as a methylene group and an ethylene group. A carbon number of the alkylene group is not particularly limited, and may be, for example, 1 to 6, may be 1 to 3, and may be 1 to 2. The site having the dimethyl silicone chain further includes the alkylene group, and thus water repellency and lipophilicity can be adjusted.

Further, a molecular weight of the site having the dimethyl silicone chain is preferably 200 or more and 8,000 or less, more preferably 240 or more and 7,600 or less, and further preferably 300 or more and 7,600 or less. Further, a molecular weight may be 300 or more and 8,000 or less.

With a molecular weight in the range described above, water repellency and lipophilicity of the dimethyl silicone chain can be further enhanced.

By changing a kind of a second compound that includes the site having the dimethyl silicone chain and has a reactive functional group, a silicon number of the dimethyl silicone chain can be adjusted, the site having the dimethyl silicone chain can have the alkylene group, and a molecular weight of the site having the dimethyl silicone chain can be adjusted.

In the solid product and the laminated body according to the present disclosure, a proportion with respect to mass of the site having the dimethyl silicone chain to the site having the alkyl group described above in the polymer brush is represented by P_{B}/P_{A} in which peak strength derived from the site having the alkyl group when the surface of the solid product or the laminated body is measured by a microscopic Raman spectroscopy device is P_{A}, and peak strength derived from the site having the dimethyl silicone chain is P_{B}. P_{B}/P_{A} is preferably 0.0 to 1.1, more preferably 0.1 or more and 1.0 or less, and further preferably 0.1 or more and 0.5 or less. With P_{B}/P_{A} in the range described above, scratch resistance can be made more excellent. Further, P_{B}/P_{A} may be 0.3 to 0.7, and an antifouling property of the solid product or the laminated body can be made more excellent with P_{B}/P_{A} in this range.

P_{B}/P_{A} can be adjusted by a mass-based ratio of a content of the second compound that includes the site having the dimethyl silicone chain and has the reactive functional group to a content of the first compound that includes the site having the alkyl group and has the hydroxyl group in a surface formation material.

P_{B}/P_{A} can be obtained by the following method.

A region of the surface of the solid product or the laminated body to be a target of measurement by the microscopic Raman spectroscopy device is decided. The region is decided by magnification of an object lens attached to the device, a wavelength of excitation laser, and an aperture diameter. Hereinafter, the decided region is also referred to as a measurement region.

Next, for the measurement region, excitation laser light is applied, generated scattered light is measured, and a peak is acquired. Measurement conditions are as follows.
Measurement device: microscopic Raman spectroscopy device made by Thermo Fisher Scientific K.K.
Object lens magnification: 10 magnifications
Excitation laser wavelength: 532 nm
Aperture diameter: 25 m
Measurement region: 2 m

Among acquired peaks in a Raman spectrum, a peak derived from a C—C bond is set as a peak derived from the site having the alkyl group, and peak strength of the peak is set as P_{A}. Further, among the acquired peaks in the Raman spectrum, a peak derived from an Si—C bond is set as a peak derived from the site having the dimethyl silicone chain, and peak strength of the peak is set as P_{B}. P_{B}/P_{A} is calculated from acquired P_{A} and P_{B}.

### <Method for Manufacturing Solid Product>

Next, the method for manufacturing the solid product according to the present disclosure will be described.

The method for manufacturing the solid product includes: in this order, a first vapor deposition step of vacuum-depositing a first vapor deposition material including silicon oxide, and forming a layer containing the silicon oxide; and a second vapor deposition step of vacuum-depositing a second vapor deposition material including a first compound that includes a site having an alkyl group having a carbon number of 14 or more and 65 or less and has a hydroxyl group, and forming the polymer brush.

In the first vapor deposition step, the first vapor deposition material including the silicon oxide is vacuum-deposited, and the layer containing the silicon oxide is formed. By performing such a first vapor deposition step, the layer containing the silicon oxide can be set as a primary layer. Further, by forming the layer containing the silicon oxide by the first vapor deposition step, an active point can be formed in the silicon oxide included in the layer. As a base material of vacuum deposition, a publicly known material can be used.

The first vapor deposition material is not particularly limited as long as the material includes the silicon oxide, and examples of the first vapor deposition material include, for example, SiO₂ and Al₂O₃added-SiO₂. Further, the first vapor deposition material may further include an inorganic oxide such as Al₂O₃, ITO, and TiO₂. Herein, the silicon oxide indicates a compound represented by SiOx (x is 1 to 2, for example), SiO₂ in a composite inorganic oxide such as SiO₂—Al₂O₃, and the like.

A condition for vacuum deposition in the first vapor deposition step is not particularly limited, and a publicly known condition can be used.

In the second vapor deposition step, the second vapor deposition material including the first compound that includes the site having the alkyl group having the carbon number of 14 or more and 65 or less and has the hydroxyl group is vacuum-deposited, and the polymer brush is formed. By performing such a second vapor deposition step after the first vapor deposition step, the polymer brush can be formed on the layer containing the silicon oxide, and, furthermore, the site being included in the polymer brush and having the alkyl group having the carbon number of 14 or more and 65 or less can be bonded to the silicon oxide included in the first layer via an oxygen atom. The oxygen atom is assumed to be derived from the hydroxyl group included in the first compound. Herein, an aspect of the bond is a covalent bond.

The first compound that is included in the second vapor deposition material, includes the site having the alkyl group, and has the hydroxyl group is not particularly limited. Examples of the first compound include, for example, straight-chain aliphatic alcohol and aliphatic alcohol having a branch structure, and the first compound is preferably straight-chain alkyl alcohol indicated by a general formula: [CₙH₂ₙ₊₁]—OH. The hydroxyl group in the formula may be located at the end of the alkyl group or may be located inside, and is preferably located at the end. The first compound has the hydroxyl group, and can thus be bonded to the silicon oxide included in the layer containing the silicon oxide. n in the formula indicates a carbon number of the alkyl group, a preferable range of n is 14 or more and 65 or less, a more preferable range is 16 or more and 60 or less, a further preferable range is 18 or more and 60 or less, and a specifically preferable range is 18 or more and 40 or less.

Specific examples of the first compound that includes the site having the alkyl group and has the hydroxyl group can include compounds of A-1, A-2, A-3, and A-4 shown in Table 1.

### <Method for Manufacturing Laminated Body>

Next, the method for manufacturing the laminated body according to the present disclosure will be described.

The method for manufacturing the laminated body includes: in this order, a first vapor deposition step of vacuum-depositing a first vapor deposition material including silicon oxide, and forming the first layer; and a second vapor deposition step of vacuum-depositing a second vapor deposition material including a first compound that includes a site having an alkyl group having a carbon number of 14 or more and 65 or less and has a hydroxyl group, and forming the polymer brush layer.

In the first vapor deposition step, the first vapor deposition material including the silicon oxide is vacuum-deposited, and the first layer is formed. By performing such a first vapor deposition step, the first layer can include the silicon oxide. Further, by forming the layer containing the silicon oxide by the first vapor deposition step, an active point can be formed in the silicon oxide included in the layer. As a base material of vacuum deposition, a publicly known material can be used.

The first vapor deposition material is not particularly limited as long as the material includes the silicon oxide, and examples of the first vapor deposition material include, for example, SiO₂ and Al₂O₃added-SiO₂. Further, the first vapor deposition material may further include an inorganic oxide such as Al₂O₃, ITO, and TiO₂. Herein, the silicon oxide indicates a compound represented by SiOx (x is 1 to 2, for example), SiO₂ in a composite inorganic oxide such as SiO₂—Al₂O₃, and the like.

A condition for vacuum deposition in the first vapor deposition step is not particularly limited, and a publicly known condition can be used.

In the second vapor deposition step, the second vapor deposition material including the first compound that includes the site having the alkyl group having the carbon number of 14 or more and 65 or less and has the hydroxyl group is vacuum-deposited, and the polymer brush layer is formed. By performing such a second vapor deposition step after the first vapor deposition step, the polymer brush can be formed on the first layer, and, furthermore, the site being included in the polymer brush and having the alkyl group having the carbon number of 14 or more and 65 or less can be bonded to the silicon oxide included in the first layer via an oxygen atom. The oxygen atom is assumed to be derived from the hydroxyl group included in the first compound. Herein, an aspect of the bond is a covalent bond.

The first compound that is included in the second vapor deposition material, which includes the site having the alkyl group and has the hydroxyl group, is not particularly limited. Examples of the first compound include, for example, straight-chain aliphatic alcohol and aliphatic alcohol having a branch structure, and the first compound is preferably straight-chain alkyl alcohol indicated by a general formula: [CₙH₂ₙ₊₁]—OH. The hydroxyl group in the formula may be located at the end of the alkyl group or may be located inside, and is preferably located at the end. The first compound has the hydroxyl group, and can thus be bonded to the silicon oxide included in the first layer.

n in the formula indicates a carbon number of the alkyl group, a preferable range of n is 14 or more and 65 or less, a more preferable range is 16 or more and 60 or less, a further preferable range is 18 or more and 60 or less, and a specifically preferable range is 18 or more and 40 or less.

Specific examples of the first compound that includes the site having the alkyl group and has the hydroxyl group can include compounds of A-1, A-2, A-3, and A-4 shown in Table 1.

The first compound in the method for manufacturing the solid product and the method for manufacturing the laminated body may be straight-chain alcohol alkoxylate and may be alcohol alkoxylate having a branch structure, and is preferably straight-chain alcohol ethoxylate indicated by a general formula: [C₁,H_{2n′+1}]—O—[(CH₂)₂O]ₘ—H. The first compound has the hydroxyl group at the end of the alkoxylate, and can thus be bonded to the silicon oxide included in the layer containing the silicon oxide or the silicon oxide included in the first layer.

n′ in the formula indicates a carbon number in the alkyl group, and m in the formula indicates a degree of polymerization of the oxyethylene group. A preferable range of n′+2m indicating a total carbon number in the straight-chain alcohol ethoxylate is 14 or more and 65 or less, a more preferable range is 16 or more and 60 or less, a further preferable range is 18 or more and 60 or less, and a specifically preferable range is 18 or more and 40 or less.

A degree of polymerization of the oxyethylene group is not particularly limited, and may be 1 to 20, may be 1 to 15, and may be 1 to 10.

Specific examples of the straight-chain alcohol alkoxylate can include compounds of A-11, A-12, A-13, and A-14 shown in Table 1.

In the method for manufacturing the solid product and the method for manufacturing the laminated body, only one kind of the first compound may be used, or two or more kinds of compounds may be used in combination. In other words, examples of the first compound include at least one selected from a group including straight-chain aliphatic alcohol, aliphatic alcohol having a branch structure, straight-chain alcohol alkoxylate, and alcohol alkoxylate having a branch structure. For example, examples of the straight-chain aliphatic alcohol include 1-stearyl alcohol, 1-eicosanol, 1-triacontanol, and 1-hexacontanol, and examples of the straight-chain alcohol ethoxylate include ethylene glycol monohexadecyl ether, ethylene glycol monooctadecyl ether, ethylene glycol monooctacosyl ether, and decaethylene glycol tetracontyl ether.

The second vapor deposition material in the method for manufacturing the solid product and the method for manufacturing the laminated body may further include, in addition to the first compound, a second compound that includes a site having a dimethyl silicone chain and has a reactive functional group. The second compound that includes the site having the dimethyl silicone chain and has the reactive functional group is not particularly limited, and is preferably a compound having a structure indicated by a general formula: R—[Si(CH₃)₂O]ᵢ—R′.

i in the formula indicates a degree of polymerization of the dimethyl silicone chain, i.e., a silicon number in the dimethyl silicone chain. A preferable range of i is 3 or more and 110 or less, a more preferable range is 3 or more and 100 or less, and a further preferable range is 3 or more and 50 or less. At least one selected from a group including R and R′ in the formula is a reactive functional group that can be bonded to, via an oxygen atom, the layer containing the silicon oxide or the first layer containing the silicon oxide. Herein, the oxygen atom is assumed to be derived from the reactive functional group included in the second compound. In other words, the reactive functional group is not limited as long as the reactive functional group can be bonded to the silicon oxide, and examples of the reactive functional group include, for example, an alkoxyl group such as a methoxy group and an ethoxy group, and a hydroxyl group. Particularly, the methoxy group is preferable.

At least one selected from a group including R and R′ is the reactive functional group that can be bonded to, via the oxygen atom, the layer containing the silicon oxide or the first layer containing the silicon oxide, and thus the second compound can be bonded to the silicon oxide included in the layer containing the silicon oxide or the silicon oxide included in the first layer. Herein, an aspect of the bond is a covalent bond.

A functional group that is not the reactive functional group in the group including R and R′ is not particularly limited as long as the functional group can be bonded to the silicon oxide, and examples of the functional group include, for example, an alkyl group such as a methyl group and an ethyl group, hydrogen, and the like. Particularly, the methyl group is preferable.

The method for manufacturing the solid product and the method for manufacturing the laminated body may include a third vapor deposition step of vapor-depositing the second compound before the second vapor deposition step or after the second vapor deposition step.

Further, a molecular weight of the second compound is preferably 200 or more and 8,000 or less, more preferably 240 or more and 7,600 or less, and further preferably 300 or more and 7,600 or less. Further, a molecular weight may be 300 or more and 8,000 or less.

Specific examples of the second compound can include compounds of B-1, B-2, and B-3 shown in Table 1.

In the second vapor deposition material, a value of a mass-based ratio of a content of the second compound to a content of the first compound is preferably 0.0 or more and 1.1 or less, more preferably 0.1 or more and 1.0 or less, and further preferably 0.1 or more and 0.5 or less. Further, a value of a mass-based ratio of a content of the second compound to a content of the first compound may be 0.3 to 0.7, and, with the value in the range described above, P_{B}/P_{A} is more likely to fall within the range described above.

### <Surface Formation Method>

Next, the surface formation method according to the present disclosure will be described.

The surface formation method is a surface formation method using a vacuum deposition method. The surface formation method includes: in this order, a first vapor deposition step of vacuum-depositing a first vapor deposition material including silicon oxide, and forming a layer containing the silicon oxide; and a second vapor deposition step of vacuum-depositing a second vapor deposition material including a first compound that includes a site having an alkyl group having a carbon number of 14 or more and 65 or less and has a hydroxyl group.

In the first vapor deposition step, the first vapor deposition material including the silicon oxide is vacuum-deposited, and the layer containing the silicon oxide is formed. By performing such a first vapor deposition step, the layer containing the silicon oxide can be formed. Further, by forming the layer containing the silicon oxide by the first vapor deposition step, an active point can be formed in the silicon oxide included in the layer. As a base material of vacuum deposition, a publicly known material can be used.

The first vapor deposition material is not particularly limited as long as the material includes the silicon oxide, and examples of the first vapor deposition material include, for example, SiO₂ and Al₂O₃added-SiO₂. Further, the first vapor deposition material may further include an inorganic oxide such as Al₂O₃, ITO, and TiO₂. Herein, the silicon oxide indicates a compound represented by SiOx (x is 1 to 2, for example), SiO₂ in a composite inorganic oxide such as SiO₂—Al₂O₃, and the like.

A condition for vacuum deposition in the first vapor deposition step is not particularly limited, and a publicly known condition can be used.

In the second vapor deposition step in the surface formation method, the second vapor deposition material including the first compound that includes the site having the alkyl group having the carbon number of 14 or more and 65 or less and has the hydroxyl group is vacuum-deposited. By performing such a second vapor deposition step after the first vapor deposition step, a surface of an acquired solid product has excellent scratch resistance and an excellent long-term antifouling property.

Examples of the first compound can include the first compound described in the section of the method for manufacturing the solid product and the method for manufacturing the laminated body.

The second vapor deposition material in the surface formation method may further include, in addition to the first compound, a second compound that includes a site having a dimethyl silicone chain and has a reactive functional group. As the second compound, the second compound described in the section of the method for manufacturing the solid product and the method for manufacturing the laminated body can be used. The surface formation method may include a third vapor deposition step of vapor-depositing the second compound before the second vapor deposition step or after the second vapor deposition step.

By vapor-depositing the second compound, the surface of the acquired solid product has more excellent water repellency and more excellent oil repellency (antifouling property).

In the second vapor deposition material, a value of a mass-based ratio of a content of the second compound to a content of the first compound is preferably 0.0 or more and 1.1 or less, more preferably 0.1 or more and 1.0 or less, and further preferably 0.1 or more and 0.5 or less. With the value in the range described above, the surface of the acquired solid product has more excellent scratch resistance. Further, a value of a mass-based ratio of a content of the second compound to a content of the first compound may be 0.3 to 0.7, and, with the value in this range, the surface of the acquired solid product has a more excellent antifouling property.

### <Surface Formation Material>

Next, the surface formation material according to the present disclosure will be described.

The surface formation material includes a first compound that includes a site having an alkyl group having a carbon number of 14 or more and 65 or less and has a hydroxyl group. As the first compound, the first compound described in the section of the method for manufacturing the solid product and the method for manufacturing the laminated body can be used. The surface formation material includes the first compound, and thus a surface acquired by performing surface treatment on a base material by using the surface formation material has both excellent scratch resistance and an excellent long-term antifouling property.

The surface formation material can be used as the second vapor deposition material in the section of the method for manufacturing the solid product, the method for manufacturing the laminated body, and the surface formation method.

The surface formation material may include a second compound that includes a site having a dimethyl silicone chain and has a reactive functional group. As the second compound, the second compound described in the section of the method for manufacturing the solid product and the method for manufacturing the laminated body can be used. The surface formation material includes the second compound, and thus the surface acquired by performing surface treatment on the base material by using the surface formation material has both of more excellent water repellency and more excellent oil repellency (antifouling property).

In the surface formation material, a value of a mass-based ratio of a content of the second compound to a content of the first compound is preferably 0.0 or more and 1.1 or less, more preferably 0.1 or more and 1.0 or less, and further preferably 0.1 or more and 0.5 or less. With the value in the range described above, the surface acquired by performing surface treatment on the base material by using the surface formation material has more excellent scratch resistance. Further, a value of a mass-based ratio of a content of the second compound to a content of the first compound may be 0.3 to 0.7, and, with the value in this range, the surface acquired by performing surface treatment on the base material by using the surface formation material can have a more excellent antifouling property.

### <Optical Member>

An optical member is an optical member including the solid product or the laminated body according to the present disclosure.

Examples of the optical member include an optical filter, an optical lens, a spectacle lens, a picture lens, a display cover glass, various films, and the like.

### <Spectacles>

Spectacles are spectacles including the optical member according to the present disclosure. The spectacles include general instruments worn around an eye, are not limited to normal spectacles for vision correction, and include plain-glass spectacles, protection goggles, a head-mounted display, sunglasses, smartglasses, and the like.

### <Touch Panel>

A touch panel is a touch panel including the optical member according to the present disclosure. The touch panel according to the present disclosure is used for general equipment including a touch panel. Examples of the equipment including the touch panel include, for example, a smartphone, a tablet terminal, and the like.

In other words, a smartphone includes the optical member according to the present disclosure. Further, a tablet terminal includes the optical member according to the present disclosure.

TABLE 1

| No. | STRUCTURE |
|---|---|
| A-1 | [C₁₈H₃₇]—OH |
| A-2 | [C₂₀H₄₁]—OH |
| A-3 | [C₃₀H₆₁]—OH |
| A-4 | [C₆₀H₁₂₁]—OH |
| A-5 | [C₁₀H₂₁]—OH |
| A-6 | [C₇₀H₁₄₁]—OH |
| A-11 | [C₁₆H₃₃]—O—[(CH₂)₂O]—H |
| A-12 | [C₁₈H₃₇]—O—[(CH₂)₂O]—H |
| A-13 | [C₂₈H₅₇]—O—[(CH₂)₂O]—H |
| A-14 | [C₄₀H₈₁]—O—[(CH₂)₂O]₁₀—H |
| B-1 | HO—[Si(CH₃)₂O]₃—H |
| B-2 | CH₃—[Si(CH₃)₂O]₂₀—Si[OCH₃]₃ |
| B-3 | CH₃—[Si(CH₃)₂O]₁₀₀—[CH₂]₃—O—[CH₂]₂—OH |

An analysis method according to the present disclosure will be described below.

### <Method for Checking Whether Site Having Alkyl Group is Bonded to Silicon Oxide Via Oxygen Atom>

Whether a site having an alkyl group is bonded to silicon oxide via an oxygen atom can be checked by the following procedures.

A first vapor deposition material including silicon oxide is vacuum-deposited on each of a base material A formed of borosilicate glass and a base material B formed of borosilicate glass, and a layer containing the silicon oxide is formed. By forming the layer containing the silicon oxide by such a first vapor deposition step, an active point can be formed in the silicon oxide included in the layer. Subsequently, while the base material A maintains a vacuum state after formation of the layer containing the silicon oxide, a second vapor deposition material is then vacuum-deposited, and thus the solid product according to the present disclosure is acquired. The base material B is taken out of a vacuum deposition device after formation of the layer containing the silicon oxide and exposed under atmospheric pressure and air, and thus the second vapor deposition material is vacuum-deposited after processing of causing the active point of the silicon oxide included in the layer to disappear is performed.

By heating, in a vacuum, the base material A and the base material B on which the second vapor deposition material is vacuum-deposited, and comparing a temperature at which a site having an alkyl group is detected by a mass analysis device (trade name: infiTOF-DUO made by KANOMAX JAPAN INCORPORATED), a fact that the site having the alkyl group is bonded to the silicon oxide via the oxygen atom can be checked. The site having the alkyl group in the base material A is bonded to the silicon oxide via the oxygen atom, and thus a temperature at which the site having the alkyl group is detected is higher than that of the base material B. Measurement conditions are as follows.
Temperature range: room temperature to 1,000° C.
Rate of temperature rise: 10° C./minutes
Atmosphere: decompressed state (5×10⁻⁷ Pa or less)
Measurement mass range: m/z 1 to 1,000

Further, a fact that the site having the alkyl group is bonded to the silicon oxide via the oxygen atom indicates that a solid product includes a polymer brush on the layer containing the silicon oxide.

### First Embodiment

The FIGURE is a schematic diagram illustrating a configuration in a first embodiment of the solid product or the laminated body according to the present disclosure, and illustrates a configuration example of the solid product or the laminated body in which a first layer (layer containing silicon oxide) 12 containing silicon oxide is formed on a base material 11 and a polymer brush 13 is formed on the first layer 12. Note that The FIGURE schematically represents the configuration including the polymer brush, and does not represent an accurate ratio of actual thicknesses of the base material 11, the first layer 12, and the polymer brush 13.

### (Base Material 11)

The base material 11 may be a solid product and allow formation of the first layer 12 containing the silicon oxide and the polymer brush 13, and examples of the base material 11 include, for example, glass, ceramics, resin, metal, a film formed of glass, resin, and the like, or the like. When the material described above is used as a base material of an optical member including the solid product or the laminated body according to the present disclosure, the base material may preferably pass visible light or light with a specific wavelength. A thickness of the base material is not particularly limited, and can be appropriately set according to use.

### (First Layer 12 Containing Silicon Oxide)

The first layer 12 containing the silicon oxide is the first layer containing the silicon oxide according to the present disclosure described above.

A thickness of the layer 12 is not particularly limited, and examples of the thickness include, for example, a thickness of 2 nm to 50 nm and a thickness of 4 nm to 20 nm.

### (Polymer Brush 13)

The polymer brush 13 is a polymer brush on the first layer containing the silicon oxide according to the present disclosure described above.

A thickness of the polymer brush 13 is not particularly limited, and examples of the thickness include, for example, a thickness of 1 nm to 10 nm and a thickness of 1 nm to 5 nm. With the thickness in the range described above, a solid product or a laminated body having excellent scratch resistance and an excellent long-term antifouling property is more likely to be acquired.

### EXAMPLES

The present disclosure will be more specifically described below with examples, but the present disclosure is not limited to the examples below.

### Example 1

### (Production of Surface Formation Material)

Table 2 shows a combination of a component A (first compound) and a component B (second compound) and a mass ratio of the component B to the component A. A structure of a material corresponding to a symbol in Table 2 is shown in Table 1. In Example 1, 30 mg of 1-triacontanol (made by Tokyo Chemical Industry Co., Ltd., product name: 1-Triacontanol) being A-3 in Table 1 as the component A was set as a surface formation material and put in a metal container (Manufacturing Example 1).

### (Production of Layer Containing Silicon Oxide)

SiO₂ (made by Canon Optron, Inc., product name: SiO₂-E-1-2) was used as a first vapor deposition material, and the first layer 12 containing the silicon oxide, being formed of SiO₂, and having a thickness of 10 nm was formed on borosilicate glass being the base material 11 and having a thickness of 3 mm by a vapor deposition method by using a vacuum deposition device (dome diameter of (900 mm, vapor deposition distance of 890 mm). A thickness of the first layer 12 containing the silicon oxide was measured by using spectroscopic ellipsometry (-ESM300 made by J.A.Woollam Co., Inc.) and was 10 nm.

### (Production of Polymer Brush)

The surface formation material according to Manufacturing Example 1 was used as a second vapor deposition material, the polymer brush 13 was formed on the first layer 12 containing silicon oxide by the vapor deposition method by using the vapor deposition device (dome diameter of (900 mm, vapor deposition distance of 890 mm), and an optical member was acquired. A thickness of the polymer brush 13 was measured by using the spectroscopic ellipsometry (-ESM300 made by J.A.Woollam Co., Inc.) and was 3 nm.

### (Evaluation of Scratch Resistance)

For a surface of the produced optical member, scratch resistance of the surface was evaluated according to the following method.

First, for the surface of the produced optical member, a water contact angle was measured by a method described below.

Subsequently, steel wool (made by Nippon Steel Wool Co., Ltd., grade #0000, wire diameter: about 0.012 mm) cut into 1 cm² was used, the steel wool was brought into contact with the surface of the optical member and caused to reciprocate, and a friction test was performed. At this time, an applied load was adjusted in such a way that a load applied to the surface was 9.8 kgf, and friction was applied in conditions that a reciprocating speed was 60 reciprocating times/minute and a movement distance was 15 mm. The number of times of friction was 1,000 reciprocating times. Subsequently, a water contact angle was measured.

The water contact angle is an angle formed between a solid surface, and a tangent to a waterdrop surface at a point at which a solid and a waterdrop are in contact. Herein, a smaller difference in the water contact angle before and after friction represents fewer scratches on the surface. In other words, a smaller difference in the water contact angle before and after friction represents higher scratch resistance. Further, when a difference in the water contact angle before and after friction is small and an evaluation of an antifouling property described below is excellent, it can be determined that a long-term antifouling property is excellent.

The water contact angle was measured by using a contact angle gauge (CA-X150 made by Kyowa Interface Science Co., Ltd). Specific procedures of the measurement are as follows.

2.5 μL of ion exchange water was dropped onto the surface of the optical member. An angle formed between the optical member surface, and a tangent to a waterdrop surface at a point at which a waterdrop and the optical member surface are in contact was measured from an image acquired after 5 seconds of the drop.

The evaluation results of scratch resistance are shown in Table 3.

### (Evaluation of Antifouling Property)

For the surface of the produced optical member, an antifouling property of the surface was evaluated according to the following method. As an indicator indicating an antifouling property, a degree that ink of a fluorescent marker was repelled and ease of wiping were set as evaluation indicators, and an evaluation was performed based on the following criteria. The results are shown in Table 3.

### (Evaluation Criteria)

A: After a tip of the pen adhered to the surface, the ink was repelled in a spherical shape within 5 seconds, and all the ink could be wiped with a cotton sheet.
B: After a tip of the pen adhered to the surface, the ink was not repelled after 5 seconds, and all the ink could be wiped by being rubbed with a cotton sheet.
C: After a tip of the pen adhered to the surface, the ink was not repelled after 5 seconds, and could not be wiped even by being rubbed with a cotton sheet.

### Examples 2 to 21

Similarly to Example 1 except that the compounds described in Table 1 as the component A and the component B were used in a combination and a mass ratio of the component B to the component A described in Table 2, a surface formation material was produced, and Manufacturing Examples 2 to 21 were acquired. An optical member was acquired by using acquired Manufacturing Examples 2 to 21. Further, similarly to Example 1, an evaluation of scratch resistance and an evaluation of an antifouling property were performed. The results are shown in Table 3.

Note that, when P_{B}/P_{A} in an acquired solid product or an acquired laminated body was measured by a microscopic Raman spectroscopy device, a mass ratio of the component B to the component A in the surface formation material coincided.

### Example 22

Similarly to Example 1 except that SiO₂ (made by Canon Optron, Inc., product name: SiO2-E-1-2) and Al₂O₃ (made by Canon Optron, Inc., product name: Al₂O₃-A-1-2) were used as a first vapor deposition material, an optical member was acquired. A proportion of mass of Al₂O₃ was adjusted in such a way as to be 0.01 to mass of SiO₂. Further, similarly to Example 1, an evaluation of scratch resistance and an evaluation of an antifouling property were performed. The results are shown in Table 3.

### Comparative Examples 1 to 3

Similarly to Example 1 except that the compounds described in Table 1 as the component A and the component B were used in a combination and a mass ratio of the component B to the component A described in Table 2, a surface formation material was produced, and Manufacturing Comparative Examples 1 to 3 were acquired. An optical member was acquired by using acquired Manufacturing Comparative Examples 1 to 3. Further, similarly to Example 1, an evaluation of scratch resistance and an evaluation of an antifouling property were performed. The results are shown in Table 3.

### Comparative Example 4

Chloromethylphenylethyltrimethoxysilane (0.564 parts by volume) was added to a mixed solution of a 0.01 M HCl aqueous solution (1 part by volume), tetraethoxysilane (2.8 parts by volume), and ethanol (8 parts by volume), the solution was mixed at a room temperature for 24 hours, and a precursor liquid was adjusted.

The precursor liquid was dropped onto a silicon wafer, spin coating (2,000 rpm/10 seconds) was performed, the silicon wafer was then dried at a room temperature for 24 hours, and a polymerization initiation layer was formed on a surface of the silicon wafer.

Methacrylic acid 2-(dimethylamino)ethyl (5.5 parts by volume), copper (II) chloride (4 parts by volume), N,N,N′,N″,N″-pentamethyl diethylene triamine (7 parts by volume), sodium ascorbate (1 part by volume), and water (1 part by volume) were mixed, and a polymerization solution was acquired. The silicon wafer on which the above-described polymerization initiation layer was formed was immersed in the polymerization solution for 2 hours, a polymer brush was formed on the surface of the silicon wafer being a base material, and an optical member was acquired. Further, similarly to Example 1, an evaluation of scratch resistance and an evaluation of an antifouling property were performed. As a result, a contact angle before friction was 65°, and a contact angle after 1,000 times of friction was 7°. An evaluation result of an antifouling property was C.

TABLE 2

| | | | COMPONENT B/ |
|---|---|---|---|
| | COMPONENT | COMPONENT | COMPONENT A |
| | A | B | (MASS RATIO) |
| MANUFACTURING EXAMPLE1 | A-3 | — | 0.0 |
| MANUFACTURING EXAMPLE2 | A-3 | B-2 | 0.1 |
| MANUFACTURING EXAMPLE3 | A-3 | B-2 | 0.5 |
| MANUFACTURING EXAMPLE4 | A-3 | B-2 | 1.0 |
| MANUFACTURING EXAMPLE5 | A-1 | — | 0.0 |
| MANUFACTURING EXAMPLE6 | A-2 | — | 0.0 |
| MANUFACTURING EXAMPLE7 | A-4 | — | 0.0 |
| MANUFACTURING EXAMPLE8 | A-11 | — | 0.0 |
| MANUFACTURING EXAMPLE9 | A-14 | — | 0.0 |
| MANUFACTURING EXAMPLE10 | A-13 | — | 0.0 |
| MANUFACTURING EXAMPLE11 | A-13 | B-2 | 0.1 |
| MANUFACTURING EXAMPLE12 | A-13 | B-2 | 0.5 |
| MANUFACTURING EXAMPLE13 | A-13 | B-2 | 1.0 |
| MANUFACTURING EXAMPLE14 | A-1 | B-2 | 0.5 |
| MANUFACTURING EXAMPLE15 | A-2 | B-2 | 0.5 |
| MANUFACTURING EXAMPLE16 | A-4 | B-2 | 0.5 |
| MANUFACTURING EXAMPLE17 | A-11 | B-2 | 0.5 |
| MANUFACTURING EXAMPLE18 | A-12 | B-2 | 0.5 |
| MANUFACTURING EXAMPLE19 | A-14 | B-2 | 0.5 |
| MANUFACTURING EXAMPLE20 | A-3 | B-1 | 0.5 |
| MANUFACTURING EXAMPLE21 | A-3 | B-3 | 0.5 |
| MANUFACTURING COMPARATIVE | — | B-2 | — |
| EXAMPLE 1 | | | |
| MANUFACTURING COMPARATIVE | A-5 | — | 0.0 |
| EXAMPLE 2 | | | |
| MANUFACTURING COMPARATIVE | A-6 | — | 0.0 |
| EXAMPLE 3 | | | |

TABLE 3

| | | CONTACT ANGLE | CONTACT ANGLE | |
|---|---|---|---|---|
| | | BEFORE FRICTION | AFTER 1,000 TIMES | ANTIFOULING |
| | MANUFACTURING NUMBER | [°] | OF FRICTION [°] | PROPERTY |
| EXAMPLE 1 | MANUFACTURING EXAMPLE 1 | 106 | 102 | B |
| EXAMPLE 2 | MANUFACTURING EXAMPLE 2 | 107 | 101 | B |
| EXAMPLE 3 | MANUFACTURING EXAMPLE 3 | 108 | 101 | A |
| EXAMPLE 4 | MANUFACTURING EXAMPLE 4 | 107 | 92 | A |
| EXAMPLE 5 | MANUFACTURING EXAMPLE 5 | 106 | 103 | B |
| EXAMPLE 6 | MANUFACTURING EXAMPLE 6 | 107 | 104 | B |
| EXAMPLE 7 | MANUFACTURING EXAMPLE 7 | 103 | 95 | B |
| EXAMPLE 8 | MANUFACTURING EXAMPLE 8 | 101 | 99 | B |
| EXAMPLE 9 | MANUFACTURING EXAMPLE 9 | 99 | 95 | B |
| EXAMPLE 10 | MANUFACTURING EXAMPLE 10 | 100 | 99 | B |
| EXAMPLE 11 | MANUFACTURING EXAMPLE 11 | 101 | 98 | B |
| EXAMPLE 12 | MANUFACTURING EXAMPLE 12 | 101 | 94 | A |
| EXAMPLE 13 | MANUFACTURING EXAMPLE 13 | 106 | 89 | A |
| EXAMPLE 14 | MANUFACTURING EXAMPLE 14 | 109 | 100 | A |
| EXAMPLE 15 | MANUFACTURING EXAMPLE 15 | 108 | 100 | A |
| EXAMPLE 16 | MANUFACTURING EXAMPLE 16 | 105 | 89 | A |
| EXAMPLE 17 | MANUFACTURING EXAMPLE 17 | 102 | 93 | A |
| EXAMPLE 18 | MANUFACTURING EXAMPLE 18 | 100 | 95 | A |
| EXAMPLE 19 | MANUFACTURING EXAMPLE 19 | 98 | 95 | A |
| EXAMPLE 20 | MANUFACTURING EXAMPLE 20 | 107 | 102 | A |
| EXAMPLE 21 | MANUFACTURING EXAMPLE 21 | 108 | 100 | A |
| EXAMPLE 22 | MANUFACTURING EXAMPLE 1 | 105 | 102 | B |
| COMPARATIVE | MANUFACTURING COMPARATIVE | 109 | 6 | A |
| EXAMPLE 1 | EXAMPLE 1 | | | |
| COMPARATIVE | MANUFACTURING COMPARATIVE | 105 | 52 | C |
| EXAMPLE 2 | EXAMPLE 2 | | | |
| COMPARATIVE | MANUFACTURING COMPARATIVE | 101 | 45 | C |
| EXAMPLE 3 | EXAMPLE 3 | | | |

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

What is claimed is:

1. A solid product comprising:
a layer containing silicon oxide; and
a polymer brush on the layer containing the silicon oxide, wherein the polymer brush constitutes a surface of the solid product,
the polymer brush includes a site having an alkyl group having a carbon number of 14 to 65,
the site having the alkyl group is bonded to the silicon oxide via an oxygen atom, and
the polymer brush further includes a site having a dimethyl silicone chain having a silicon number of 3 to 110, and the site having the dimethyl silicone chain is bonded to the silicon oxide via an oxygen atom.

2. The solid product according to claim 1, wherein the site having the alkyl group further has oxyethylene group-(CH₂)₂—O—.

3. The solid product according to claim 1, wherein the site having the alkyl group is a straight-chain aliphatic structure.

4. The solid product according to claim 1, wherein the site having the alkyl group is a straight-chain alkyl group having oxyethylene group-(CH₂)₂—O—.

5. The solid product according to claim 1, wherein a molecular weight of the site having the dimethyl silicone chain is 200 to 8,000.

6. An optical member comprising the solid product according to claim 1.

7. A spectacle comprising the optical member according to claim 6.

8. A touch panel comprising the optical member according to claim 6.

9. A smartphone comprising the optical member according to claim 6.

10. A tablet terminal comprising the optical member according to claim 6.

11. A surface formation method using a vacuum deposition method, the surface formation method comprising:
in this order,
a first vapor deposition step of vacuum-depositing a first vapor deposition material including silicon oxide, and forming a layer containing the silicon oxide; and
a second vapor deposition step of vacuum-depositing a second vapor deposition material including a first compound that includes a site having an alkyl group having a carbon number of 14 to 65 and has a hydroxyl group, and
the second vapor deposition material further includes a second compound that includes a site having a dimethyl silicone chain and has a reactive functional group.

12. The surface formation method according to claim 11, wherein the first compound is straight-chain aliphatic alcohol.

13. The surface formation method according to claim 11, wherein the first compound is straight-chain alcohol ethoxylate.

14. The surface formation method according to claim 11, wherein a value of a ratio of a content of the second compound to a content of the first compound in the second vapor deposition material is 0.1 to 1.0.

15. A solid product including a surface formed by the surface formation method according to claim 11.

16. An optical member comprising the solid product according to claim 15.

17. A spectacle comprising the optical member according to claim 16.

18. A touch panel comprising the optical member according to claim 16.

19. A smartphone comprising the optical member according to claim 16.

20. A tablet terminal comprising the optical member according to claim 16.
